(19) United States
(12) Patent Application Publication
(10) Pub. No.: US 2025/0287508 A1
(43) Pub. Date: Sep. 11, 2025

(54) CARRIER-ATTACHED ULTRA-THIN COPPER FOIL AND MANUFACTURING METHOD THEREOF

(71) Applicants: National Tsing Hua University, HSINCHU CITY (TW); Chang Chun Plastics Co., Ltd, TAIPEI (TW); Chang Chun PetroChemical Co., Ltd, TAIPEI (TW); DAIREN CHEMICAL CORPORATION, Kaohsiung City (TW)

(72) Inventors: TZU-CHIEN WEI, HSINCHU CITY (TW); VIDYA KATTOOR, HSINCHU CITY (TW); An-Pang Tu, Taipei City (TW); Chia-Hung Wu, Taipei City (TW)

(21) Appl. No.: 18/748,121

(22) Filed: Jun. 20, 2024

(30) Foreign Application Priority Data
Mar. 7, 2024 (TW) 113108259

(51) Int. Cl. H05K 3/02; C23C 18/16; C23C 18/38; H05K 1/09; H05K 3/38

(52) U.S. Cl. CPC H05K 3/025; C23C 18/1641; C23C 18/1653; C23C 18/1657; C23C 18/38; H05K 1/095; H05K 3/384

(57) ABSTRACT

A carrier-attached ultra-thin copper foil and a method for manufacturing the same are provided. The method includes modifying a polymer substrate with an amine-based polymer compound to form a modification layer on at least one surface of the polymer substrate. A palladium catalyst is then used to activate the modification layer, thereby forming an activation layer on the modification layer. Subsequently, an ultra-thin copper foil is formed on the activation layer, in which the polymer substrate can be separated from the ultra-thin copper foil via the modification layer and the activation layer.

### CROSS-REFERENCE TO RELATED PATENT APPLICATION

This application claims the benefit of priority to Taiwan Patent Application No. 113108259, filed on Mar. 7, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a copper foil, and more particularly to a carrier-attached ultra-thin copper foil and a manufacturing method thereof.

### BACKGROUND OF THE DISCLOSURE

In current 5th generation (5G) technology, electronic devices are required to be smaller, lighter, thinner, and shorter, necessitating the miniaturization of their dimensions and the reduction of power consumption. At the same time, the printed circuit boards (PCBs) within these devices also need to be decreased in size. Consequently, thinning of the metal copper layers and designing printed circuit boards with fine circuitry have become essential in the industry. Therefore, to meet market demands, peelable carrier copper foils are extensively used in the production of printed circuit boards. The standard for peelable carrier copper foils is to have optimal peeling strength between the substrate and the copper layer, ensuring uniformity during the peeling process.

The carrier copper foil, insulating resin substrate, and polyimide are bonded together through thermal pressing to form a copper-clad laminate (CCL) used in manufacturing printed circuit boards. A conventional carrier copper foil typically includes a carrier, a release layer, and an ultra-thin copper foil. An organic release layer containing organic compounds (e.g., nitrogen-containing compounds) is commonly used. The advantages of the release layer include: (1) ease of forming an ultra-thin copper foil; and (2) maintaining uniform peeling strength between the ultra-thin copper foil and the supporting metal layer.

When the release layer is peeled off, even after lamination under high temperatures, the carrier can be separated from the ultra-thin copper foil. Since the release layer remains on the carrier, the release layer needs to be easily removable so that the carrier can be readily reused.

Multilayer printed circuit boards require further reduction in thickness of interlayer insulating films, as well as a reduction in weight of the circuit boards.

Therefore, in recent years, a coreless construction method has been adopted in the manufacture of multilayer printed circuit boards, where insulating resin layers and conductor layers are alternately laminated without using a so-called core substrate.

However, for multiple laminations undergoing high temperatures and long durations, such as the coreless lamination method, there is a problem where the peeling strength between the carrier foil and the ultra-thin copper foil significantly increases. Moreover, maintaining stable peeling strength that is not easily peelable between the carrier foil and the ultra-thin copper foil during long-term thermal processes poses a significant challenge, but is needed to ensure adhesive properties of the peeling strength.

### SUMMARY OF THE DISCLOSURE

In response to the above-referenced technical inadequacies, the present disclosure provides a carrier-attached ultra-thin copper foil and a manufacturing method thereof.

In one aspect, the present disclosure provides a method for manufacturing a carrier-attached ultra-thin copper foil, including a surface functionalization step, a surface activation step, and a copper layer formation step. The surface functionalization step includes using an amine-based polymer compound to modify a polymer substrate, so as to form a modification layer on at least one surface of the polymer substrate. The surface activation step includes using a palladium catalyst to activate the modification layer, so as to form an activation layer on a surface of the modification layer away from the polymer substrate. The copper layer formation step includes forming an ultra-thin copper foil on a surface of the activation layer away from the modification layer, thereby producing the carrier-attached ultra-thin copper foil. The polymer substrate is capable of being separated (or is peelable) from the ultra-thin copper foil through the modification layer and the activation layer.

In another aspect, the present disclosure provides a carrier-attached ultra-thin copper foil that includes a polymer substrate, a modification layer, an activation layer, and an ultra-thin copper foil. The modification layer is formed on at least one surface of the polymer substrate, and the modification layer is formed of an amine-based polymer compound. The activation layer is formed on a surface of the modification layer away from the polymer substrate, and the activation layer is formed of a palladium catalyst. The ultra-thin copper foil is formed on a surface of the activation layer away from the modification layer. The polymer substrate is capable of being separated (or is peelable) from the ultra-thin copper foil via the modification layer and the activation layer.

Therefore, the carrier-attached ultra-thin copper foil and the manufacturing method thereof provided by the present disclosure can produce stable peeling strength and enhanced release properties by virtue of “using an amine-based polymer compound to functionally modify a polymer substrate to form a modification layer on at least one surface of the polymer substrate,” “using a palladium catalyst to activate the modification layer to form an activation layer on a surface of the modification layer away from the polymer substrate,” “forming an ultra-thin copper foil on a surface of the activation layer away from the modification layer, thus producing the carrier-attached ultra-thin copper foil,” and “the polymer substrate capable of being separated from the ultra-thin copper foil through the modification layer and the activation layer.”

Furthermore, in related art, the problems associated with significantly increased peeling strength between the carrier and the thin copper foil under long-term and high-temperature processing conditions required for multiple thermal press moldings can be effectively improved.

The carrier-attached ultra-thin copper foil provided by the present disclosure is suitable for high-temperature processes over long periods of time while maintaining stable peeling strength between the carrier and the thin copper foil.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view showing step S110 of a manufacturing method of a carrier-attached ultra-thin copper foil according to an embodiment of the present disclosure;

FIG. 2 is a schematic view showing step S120 of the manufacturing method of the carrier-attached ultra-thin copper foil according to the embodiment of the present disclosure;

FIG. 3 is a schematic view showing step S130 of the manufacturing method of the carrier-attached ultra-thin copper foil according to the embodiment of the present disclosure;

FIG. 4 is a schematic view showing step S140 of the manufacturing method of the carrier-attached ultra-thin copper foil according to the embodiment of the present disclosure;

FIG. 5 is a schematic view illustrating the use of the carrier-attached ultra-thin copper foil in manufacturing a printed circuit board substrate according to an embodiment of the present disclosure;

FIG. 6 is another schematic view illustrating the use of the carrier-attached ultra-thin copper foil in manufacturing the printed circuit board substrate according to the embodiment of the present disclosure;

FIG. 7 is a schematic view showing the formation of a modification layer on a polymer substrate through electrostatic interactions with an amine-based polymer compound according to the embodiment of the present disclosure;

FIG. 8 shows experimental results of a nitrogen peak measured by X-ray Photoelectron Spectroscopy (XPS) from the modification layer on the polymer substrate according to the embodiment of the present disclosure;

FIG. 9 illustrates the effect of different polyethyleneimine (PEI) concentrations on peeling strength according to the embodiment of the present disclosure; and

FIG. 10 illustrates the effect of different PVA-Pd concentrations on peeling strength according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### [Method for Manufacturing Carrier-Attached Ultra-Thin Copper Foil]

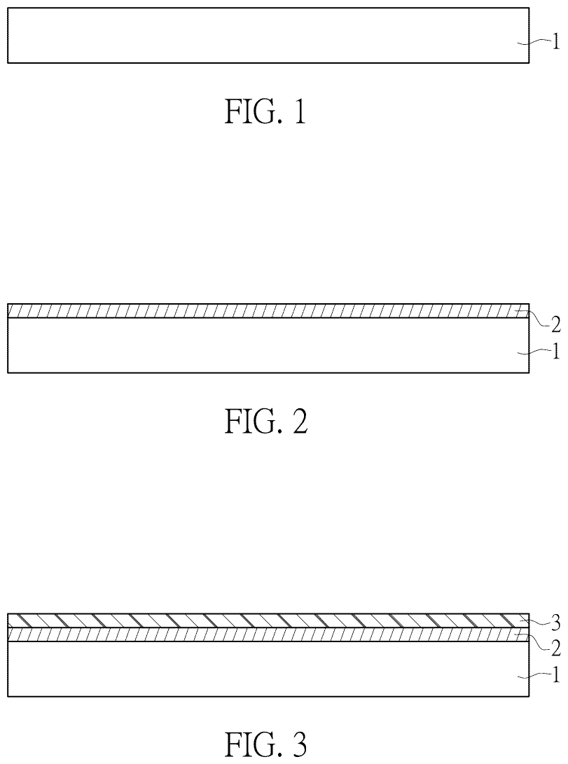

Referring to FIG. 1 to FIG. 4, an embodiment of the present disclosure provides a method for manufacturing a carrier-attached ultra-thin copper foil, which includes steps S110, S120, S130, and S140. It should be noted that orders of the steps described in the present embodiment can be adjusted according to requirements, and are not limited to those described in the present embodiment.

As shown in FIG. 1, step S110 includes providing a polymer substrate 1. In the present embodiment, the polymer substrate 1 is a liquid crystal polymer (LCP) substrate.

That is, the polymer substrate 1 can be, for example, formed of a liquid crystal polymer resin (i.e., LCP resin).

Moreover, the liquid crystal polymer resin can be prepared by derivation from at least one of the following compounds: aromatic hydroxyl compounds, aliphatic hydroxyl compounds, aromatic dicarboxylic acid compounds, aliphatic dicarboxylic acid compounds, aromatic hydroxycarboxylic acid compounds, and aromatic amine compounds.

For example, the liquid crystal polymer resin can be prepared by derivation from 6-hydroxy-2-naphthoic acid, 4-hydroxybenzoic acid, and acetic anhydride, but the present disclosure is not limited thereto.

Further, the polymer substrate 1 has a thickness between 25 micrometer and 100 micrometers, but the present disclosure is not limited thereto.

As shown in FIG. 2, step S120 is to perform a surface functionalization step, which includes: using an amine-based polymer compound to surface modify the polymer substrate 1, thereby forming a modification layer 2 on at least one surface of the polymer substrate 1.

That is, the modification layer 2 is mainly formed of the amine-based polymer compound.

In the present embodiment, the amine-based polymer compound is polyethyleneimine (PEI). That is, the modification layer 2 is a polyethyleneimine modification layer. In some embodiments of the present disclosure, the amine-based polymer compound is at least one of linear polyethyleneimine and branched polyethyleneimine.

Preferably, the amine-based polymer compound is branched polyethyleneimine. Alternatively, the amine-based polymer compound has the following chemical structure, but the present disclosure is not limited thereto.

The chemical structure of the amine-based polymer compound in the present embodiment is shown as follows.

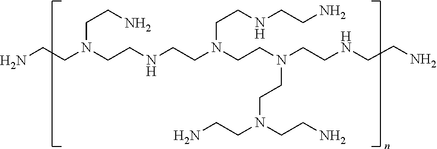

In a specific embodiment of the present disclosure, the amine-based polymer compound (polyethyleneimine) can be, for example, obtained from a polyethyleneimine solution purchased from Sigma-Aldrich (CAS No. 9002-98-6, MDL number MFCD00084427, with Mn of about 60,000 and Mw of about 750,000, but the present disclosure is not limited thereto.

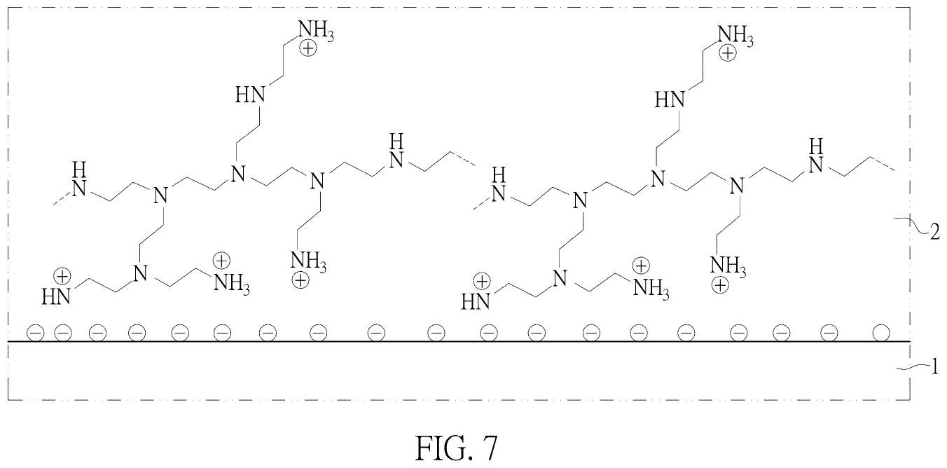

As shown in FIG. 2 and FIG. 7, in an embodiment of the present disclosure, the surface of the polymer substrate 1 (i.e., the liquid crystal polymer substrate) carries negative charges. Furthermore, the amine-based polymer compound (i.e., polyethyleneimine) is a cationic polyelectrolyte that carries positive charges when being hydrolyzed or protonated in an aqueous solution. Accordingly, the amine-based polymer compound can be adsorbed onto the negatively charged surface of the polymer substrate 1 through electrostatic interaction, thereby forming the modification layer 2.

More specifically, the polymer substrate 1 (i.e., the liquid crystal polymer substrate) is first cleaned with acetone to remove impurities from the surface thereof, and then the cleaned polymer substrate 1 is immersed in a solution containing the amine-based polymer compound (i.e., polyethyleneimine) using water as a solvent.

In the presence of water, the surface of the polymer substrate 1 slightly carries negative charges, which attracts the polyethyleneimine that slightly carries positive charges in the same solution, but the present disclosure is not limited thereto.

For example, in other embodiments of the present disclosure, the surface of the polymer substrate 1 can also be uncharged or carry positive charges, and the polyethyleneimine can be adsorbed onto the surface of the polymer substrate 1.

According to the above configuration, the surface of the polymer substrate 1 has increased hydrophilicity and surface roughness through the modification of the modification layer 2, which is beneficial for subsequent metallization processes.

More specifically, the surface functionalization step involves treating the surface of the polymer substrate 1 with a first aqueous solution containing the amine-based polymer compound (e.g., polyethyleneimine), so as to functionally modify the surface of polymer substrate 1, and form the modification layer 2 on the polymer substrate 1.

In the first aqueous solution, a volume percentage concentration of the amine-based polymer compound is preferably between 0.7 vol % and 1.3 vol %, and more preferably between 0.9 vol % and 1.1 vol %.

Furthermore, a treatment time (i.e., an immersion time) of the first aqueous solution to the polymer substrate 1 ranges from 1 minute to 10 minutes, and preferably ranges from 3 minutes to 7 minutes, but the present disclosure is not limited thereto.

Accordingly, the surface of the polymer substrate 1 can have an ideal surface roughness (e.g., Ra being 0.20 micrometers to 0.25 micrometers) through modification of the modification layer 2, and can enable the finally formed carrier-attached ultra-thin copper foil 100 to have an ideal peeling strength (e.g., 25 gf/cm to 40 gf/cm, and more preferably 30 gf/cm to 40 gf/cm), which is suitable for use as a release material.

Further, the surface of the polymer substrate 1 has a water contact angle (WCA) ranging from 55° to 65° through modification of the modification layer 2, which has increased hydrophilicity compared to an unmodified polymer substrate.

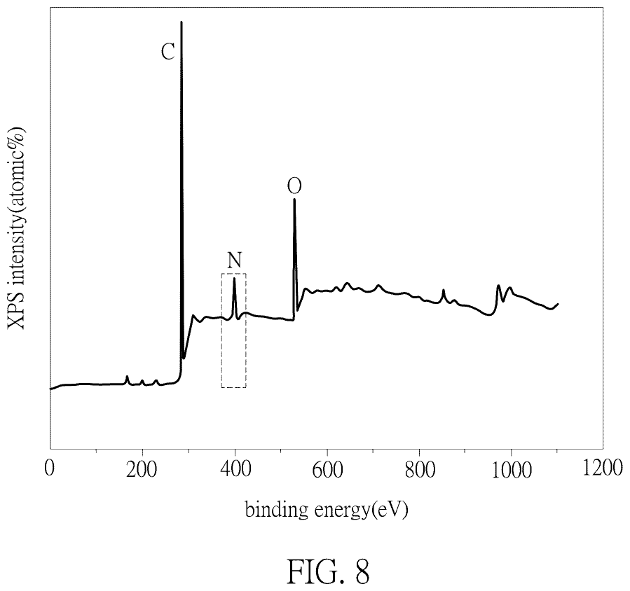

The modification layer 2 on the polymer substrate 1, as determined by X-ray photoelectron spectroscopy (XPS), exhibits a nitrogen peak, where the binding energy of the nitrogen peak is approximately at 400 eV (as shown in FIG. 8).

An elemental ratio (atomic %) of the polymer substrate 1 as determined by X-ray photoelectron spectroscopy (XPS) after being modified by the modification layer 2 is that nitrogen (N) atoms account for 3 atomic % to 9 atomic %, oxygen (O) atoms account for 10 atomic % to 20 atomic %, and carbon (C) atoms account for 75 atomic % to 85 atomic %.

In a specific embodiment, the nitrogen (N) atoms account for 5.25 atomic %, the oxygen (O) atoms account for 15.39 atomic %, and the carbon (C) atoms account for 79.35 atomic %, but the present disclosure is not limited thereto. The nitrogen atoms in the modification layer 2 are originated from the amine-based polymer compound (i.e., polyethyleneimine).

It is worth mentioning that X-ray photoelectron spectroscopy (XPS) is a quantitative spectroscopic technique used to determine the elemental composition, empirical formula, and chemical and electronic states of the elements within a material. The technique involves irradiating the material under analysis with X-rays while measuring the kinetic energy and number of electrons that escape from the material surface within a range from 1 nm to 10 nm, thereby obtaining an X-ray photoelectron spectrum.

It is worth mentioning that since the amine-based polymer compound is adsorbed onto the negatively charged surface of polymer substrate 1 through electrostatic interactions rather than being covalently bonded to the polymer substrate 1, the modification layer 2 on the polymer substrate 1 can be easily removed by solvent washing after a peeling operation, which enables the polymer substrate 1 to be reused.

As shown in FIG. 3, step S130 is to perform a surface activation step that includes using a palladium catalyst to activate the modification layer 2, so as to form an activation layer 3 on a surface of the modification layer 2 away from the polymer substrate 1.

Preferably, the palladium catalyst is a polymer-coated nano-palladium catalyst. That is, the activation layer 3 is formed of the polymer-coated nano-palladium catalyst.

In some embodiments of the present disclosure, the polymer-coated nano-palladium catalyst is prepared by a colloidal deposition method using a stabilizer such as polyvinyl alcohol (PVA) or polyvinylpyrrolidone (PVP), resulting in palladium (Pd)-based catalysts such as a polyvinyl alcohol polymer-palladium (PVA-Pd) catalyst or a polyvinyl pyrrolidone capped palladium (PVP-Pd) catalyst. Preferably, the polymer-coated nano-palladium catalyst is a PVA-Pd catalyst.

In a specific embodiment of the present disclosure, the PVA-Pd catalyst can be prepared by the following synthesis method: first, 0.285 grams of PVA are dissolved in 30 milliliters of water, with continuous stirring until completely dissolving, to prepare a PVA solution. Next, 5.29944 grams of Na₂CO₃ are dissolved in 50 milliliters of water to prepare a 1M Na₂CO₃ solution. Then, 0.329 grams of Pd(NO₃)₂ are dissolved in 14 milliliters of RO water, with stirring to aid in dissolution. Then, 30 milliliters of the prepared PVA solution are added to the Pd(NO₃)₂ solution and stirred for 30 minutes to 1 hour. Subsequently, 1 milliliter of 14% HCHO is added to the mixture and left to stand for 5 minutes. Finally, 5 milliliters of the Na₂CO₃ solution are gradually added to the mixture, with an addition rate controlled by a speed controller, so as to obtain the nano-palladium catalyst (PVA-Pd catalyst). However, the nano-palladium catalyst of the present disclosure is not limited to being obtained through the above preparation method. For example, the palladium catalyst could also be a commercially available tin-palladium colloidal catalyst or an ionic palladium catalyst.

More specifically, the surface activation step involves using a second aqueous solution containing the polymer-coated nano-palladium catalyst (e.g., PVA-Pd catalyst) to activate the modification layer 2, thereby forming the activation layer 3 on the modification layer 2.

In the second aqueous solution, a concentration of the polymer-coated nano-palladium catalyst preferably ranges from 20 ppm (parts per million) to 120 ppm, and more preferably ranges from 25 ppm to 100 ppm. For example, the concentration of the polymer-coated nano-palladium catalyst is 25 ppm, 50 ppm, 75 ppm, or 100 ppm.

Furthermore, a treatment time (i.e., an immersion time) of the second aqueous solution to the modification layer 2 ranges from 1 minute to 10 minutes, and preferably ranges from 3 minutes to 7 minutes, but the present disclosure is not limited thereto.

It is worth noting that since the polymer substrate 1 (i.e., the liquid crystal polymer substrate) is modified by the modification layer 2 (i.e., polyethyleneimine), the surface of the polymer substrate 1 has amino groups which exhibit a good affinity to the polymer-coated nano-palladium catalyst, thereby enabling the formation of complexes through electron donor-acceptor interactions, so as to facilitate the subsequent copper layer formation step.

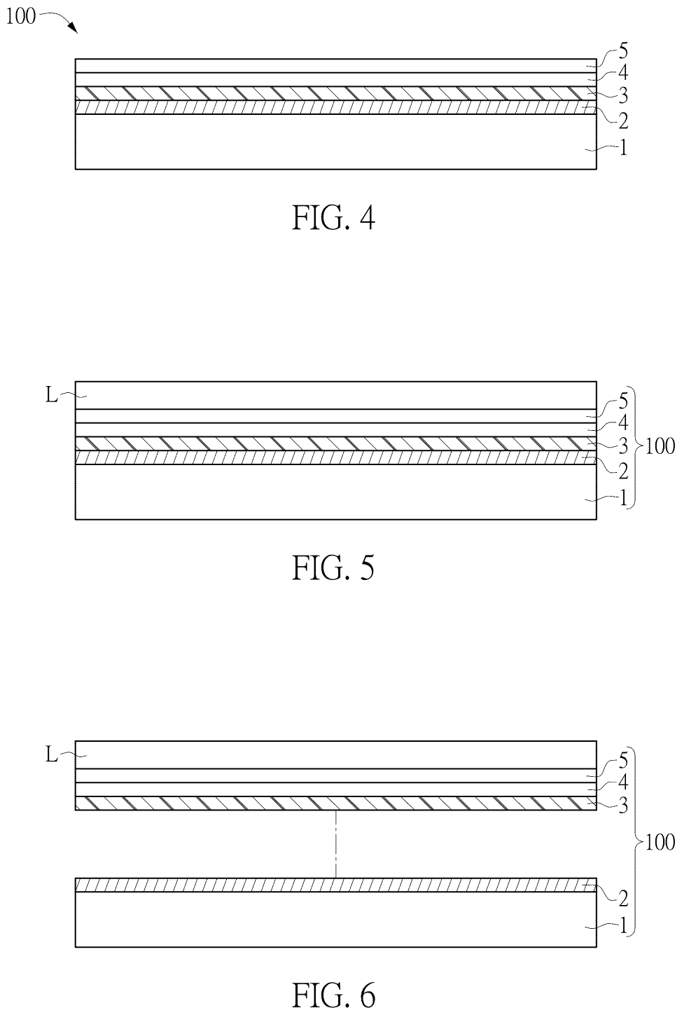

As shown in FIG. 4, step S140 is to perform a copper layer formation step that includes forming an ultra-thin copper foil on a surface of the activation layer 3 away from the modification layer 2. More specifically, the copper layer formation step involves sequentially forming a first copper layer 4 and a second copper layer 5 on the surface of the activation layer 3 away from the modification layer 2. The first copper layer 4 and the second copper layer 5 together constitute the ultra-thin copper foil.

Further, the first copper layer 4 can be an electroless copper layer formed by a chemical copper deposition process.

For example, the chemical copper deposition process includes using a copper deposition solution to deposit the first copper layer 4 on an upper surface of the activation layer 3.

In some embodiments of the present disclosure, the copper deposition solution includes 0.05 to 0.3 mol/L of a complexing agent, 1 to 5 g/L of copper ions (derived from copper sulfate), 3 to 7 g/L of sodium hydroxide, and 2 to 6 g/L of formaldehyde, where a working temperature of the copper deposition solution can be 50° C. to 55° C., and an immersion time of the copper deposition solution can be 10 minutes to 20 minutes, and preferably 15 minutes, but the method for forming the first copper layer of the present disclosure is not limited thereto.

For example, the first copper layer 4 can be also formed by methods such as sputter deposition and chemical vapor deposition.

A thickness of the first copper layer 4 ranges from 200 nanometers to 800 nanometers, preferably ranges from 300 nanometers to 700 nanometers, and more preferably ranges from 400 nanometers to 600 nanometers. For example, the thickness of the first copper layer 4 is approximately 500 nanometers, but the present disclosure is not limited thereto.

The second copper layer 5 is an electroplated copper layer formed by an electroplating copper method. The electroplating copper method can include forming the second copper layer 5 on the first copper layer 4 via a wet electroplating/electrolysis process.

A thickness of the second copper layer 5 ranges from 1 micrometer to 10 micrometers, preferably ranges from 3 micrometers to 7 micrometers, and more preferably ranges from 4 micrometers to 6 micrometers. For example, the thickness of the second copper layer 5 is approximately 5 micrometers, but the present disclosure is not limited thereto.

It is worth mentioning that, in an embodiment of the present disclosure, after forming the first copper layer 4, the first copper layer 4 firstly undergoes an annealing treatment, and the second copper layer 5 is then formed on the surface of the first copper layer 4. The conditions for the annealing treatment involve heating the first copper layer 4 to a temperature of 110° C. to 130° C. (preferably 120° C.) for 10 minutes to 30 minutes (preferably 20 minutes), and then cooling the first copper layer 4 down to a room temperature (e.g., 25° C.). The electroplating process to form the second copper layer 5 is then conducted on the surface of the first copper layer 4 that has been annealed.

According to the above technical solution, as shown in FIG. 4, the polymer substrate 1 (i.e., a liquid crystal polymer substrate), the modification layer 2 (i.e., a polyethyleneimine modification layer), the activation layer 3 (i.e., a PVA-Pd activation layer), the first copper layer 4 (i.e., an electroless copper layer), and the second copper layer 5 (i.e., an electroplated copper layer) together form a carrier-attached ultra-thin copper foil 100. In other words, the carrier-attached ultra-thin copper foil 100 includes the polymer substrate 1, the modification layer 2, the activation layer 3, the first copper layer 4, and the second copper layer 5 that are sequentially stacked on each other.

In the carrier-attached ultra-thin copper foil 100, the polymer substrate 1 is a peelable carrier. The modification layer 2 and the activation layer 3 act as composite adhesive layers, used for bonding the polymer substrate 1 to the ultra-thin copper foil composed of the first copper layer 4 and the second copper layer 5.

Furthermore, the polymer substrate 1 can be peeled from the ultra-thin copper foil composed of the first copper layer 4 and the second copper layer 5 at an interface between the modification layer 2 and the activation layer 3, as shown in FIG. 5 and FIG. 6. A peeling strength between the polymer substrate 1 and the ultra-thin copper foil preferably ranges from 25 gf/cm to 40 gf/cm, and more preferably ranges from 30 gf/cm to 40 gf/cm.

The peeling strength can be measured in accordance with JIS Z 0237-2009 (under conditions of 25° C., a peeling angle of 180°, and a peeling rate of 300 mm/min), but the present disclosure is not limited thereto.

The above is a detailed description of the manufacturing method of the carrier-attached ultra-thin copper foil 100 according to an embodiment of the present disclosure. The application of the carrier-attached ultra-thin copper foil 100, such as the use in the manufacturing substrates of printed circuit board, will be illustrated as follows, but the present disclosure is not limited thereto.

As shown in FIG. 5, the carrier-attached ultra-thin copper foil 100 can be bonded to another polymer substrate L through the second copper layer 5. In an embodiment of the present disclosure, the carrier-attached ultra-thin copper foil 100 can be more tightly bonded to the another polymer substrate L via a thermal pressing process, but the present disclosure is not limited thereto.

As shown in FIG. 6, the polymer substrate 1 of the carrier-attached ultra-thin copper foil 100 can be peeled off at the interface between the modification layer 2 and the activation layer 3, allowing the ultra-thin copper foil composed of the first copper layer 4 and the second copper layer 5 to be remained on the another polymer substrate L (e.g., another liquid crystal polymer substrate). From another perspective, a binding force between the modification layer 2 and polymer substrate 1 is greater than a binding force between the modification layer 2 and the activation layer 3. Moreover, a binding force between the activation layer 3 and the ultra-thin copper foil composed of the first copper layer 4 and the second copper layer 5, is greater than a binding force between the activation layer 3 and the modification layer 2. Accordingly, the polymer substrate 1 can be separate from the ultra-thin copper foil through the modification layer 2 and the activation layer 3.

In other words, the surface (e.g., the bottom surface) of the another polymer substrate L is sequentially covered by the second copper layer 5, the first copper layer 4, and the activation layer 3, thereby forming a printed circuit board substrate that can be used for the production of ultra-fine circuitry. Additionally, the polymer substrate 1 and the modification layer 2 are separated from the another polymer substrate L. It is worth mentioning that since the polymer substrate 1 and the modification layer 2 are attached to each other through electrostatic interactions, the modification layer 2 on the polymer substrate 1 can be easily removed by solvent washing after the peeling operation, allowing the polymer substrate 1 to be reused.

### [Effect of PEI Concentration on Peeling Strength]

In a preferred preparation example, a surface of a liquid crystal polymer substrate (LCP substrate) is first cleaned with acetone. Subsequently, the liquid crystal polymer substrate is immersed in a 1 vol % polyethyleneimine (PEI) aqueous solution at room temperature for 5 minutes to functionally modify the surface of the liquid crystal polymer substrate, thereby forming a polyethyleneimine modification layer (PEI modification layer) on the liquid crystal polymer substrate. The PEI modification layer is then rinsed with deionized water and air-dried. Afterward, the PEI modification layer on the liquid crystal polymer substrate is further activated with an aqueous solution of a polymer-capped nano-palladium catalyst (PVA-Pd), with a concentration of 50 ppm, and soaked for 5 minutes to form an activation layer. The activation layer is then rinsed with deionized water and air-dried.

Subsequently, a chemical copper deposition process is performed to form an electroless copper layer on the surface of the activated liquid crystal polymer substrate with a chemical copper deposition time of 15 minutes, and the thickness of the electroless copper layer is approximately 500 nanometers. The electroless copper layer undergoes an annealing treatment at a heating temperature of 120° C. for 20 minutes, and followed by cooling. An electroplating operation is then performed on the electroless copper layer to form an electroplated copper layer having a thickness of about 5 micrometers, thereby finally forming a carrier-attached ultra-thin copper foil. The PEI modification layer and the PVA-Pd activation layer serve as peelable adhesive layers.

Afterwards, the carrier-attached ultra-thin copper foil is bonded to another liquid crystal polymer substrate and subjected to a thermal pressing. Finally, the liquid crystal polymer substrate within the carrier-attached ultra-thin copper foil is separated from the another liquid crystal polymer substrate through the modification layer and the activation layer, and a peeling strength is measured according to JIS Z 0237-2009. The electroless copper layer and the electroplated copper layer are retained on the another liquid crystal polymer substrate.

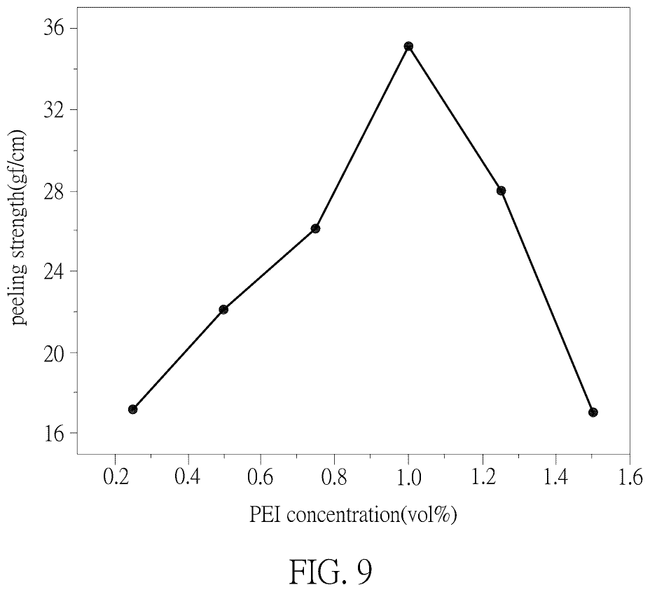

FIG. 9 illustrates the effect of different polyethyleneimine (PEI) concentrations on peeling strength.

In a preferred preparation example, a 1 vol % polyethyleneimine (PEI) aqueous solution produces an optimal peeling strength (approximately 35 gf/cm). Additionally, while other conditions are kept constant and the concentration of PEI is varied, it can be found that both decreasing and increasing the concentration will lead to a reduction in peeling strength. Considering the release effect, the concentration of the polyethyleneimine (PEI) aqueous solution is preferably between 0.7 vol % and 1.3 vol %, which can produce a peeling strength of between 25 gf/cm and 40 gf/cm.

### [Effect of PVA-Pd Concentration on Peeling Strength]

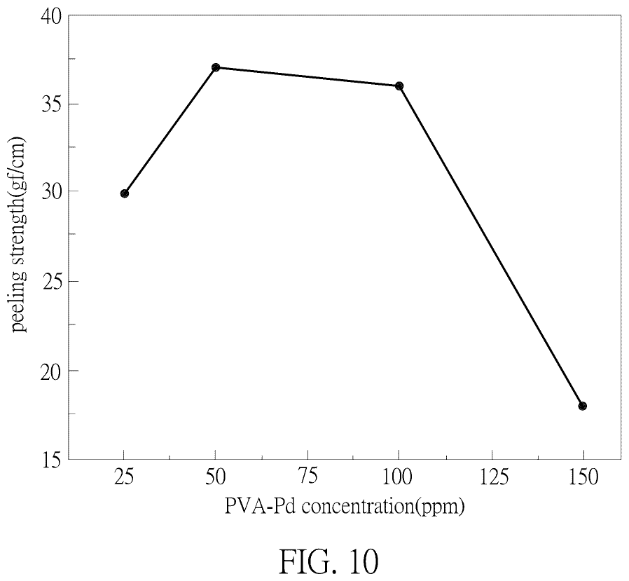

FIG. 10 illustrates the effect of different PVA-Pd concentrations on peeling strength. From FIG. 10, it is evident that in the preferred preparation example, a solution with 50 ppm of PVA-Pd produces an optimal peeling strength (approximately 35 gf/cm). Additionally, while other conditions are kept constant and the concentration of PVA-Pd is varied, it can be found that both decreasing and increasing the concentration leads to a reduction in peeling strength.

Considering the release effect, the preferred concentration of PVA-Pd ranges from 25 ppm to 100 ppm, which can produce a peeling strength between 30 gf/cm and 40 gf/cm.

### Beneficial Effects of the Embodiments

In conclusion, the carrier-attached ultra-thin copper foil and the manufacturing method thereof provided by the present disclosure can produce stable peeling strength and enhanced release properties by virtue of “using an amine-based polymer compound to functionally modify a polymer substrate to form a modification layer on at least one surface of the polymer substrate,” “using a palladium catalyst to activate the modification layer to form an activation layer on a surface of the modification layer away from the polymer substrate,” “forming an ultra-thin copper foil on a surface of the activation layer away from the modification layer, thus producing the carrier-attached ultra-thin copper foil,” and “the polymer substrate capable of being separated (peelable) from the ultra-thin copper foil through the modification layer and the activation layer.”

Furthermore, in related art, the problems associated with significantly increased peeling strength between the carrier and the thin copper foil under long-term and high-temperature processing conditions required for multiple thermal press moldings can be effectively improved. The carrier-attached ultra-thin copper foil provided by the present disclosure is suitable for high-temperature processes over long periods of time, while maintaining stable peeling strength between the carrier and the thin copper foil.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a carrier-attached ultra-thin copper foil, comprising:
a surface functionalization step that includes using an amine-based polymer compound to modify a polymer substrate, so as to form a modification layer on at least one surface of the polymer substrate;
a surface activation step that includes using a palladium catalyst to activate the modification layer, so as to form an activation layer on a surface of the modification layer away from the polymer substrate; and
a copper layer formation step that includes forming an ultra-thin copper foil on a surface of the activation layer away from the modification layer, thereby producing the carrier-attached ultra-thin copper foil;
wherein the polymer substrate is capable of being separated from the ultra-thin copper foil through the modification layer and the activation layer.

2. The method according to claim 1, wherein the polymer substrate is a liquid crystal polymer substrate, and the amine-based polymer compound is polyethyleneimine (PEI).

3. The method according to claim 2, wherein the polyethyleneimine (PEI) is adsorbed onto the liquid crystal polymer substrate through electrostatic interaction, so as to form the modification layer.

4. The method according to claim 2, wherein the surface functionalization step includes modifying the surface of the liquid crystal polymer substrate with a first aqueous solution containing polyethyleneimine (PEI), so as to form the modification layer; wherein, in the first aqueous solution, a volume percentage concentration of polyethyleneimine ranges from 0.7 vol % to 1.3 vol %.

5. The method according to claim 4, wherein a nitrogen peak is detected from the modification layer by an X-ray photoelectron spectrometer (XPS), and an elemental ratio of nitrogen atoms ranges from 3 atomic % to 9 atomic %.

6. The method according to claim 1, wherein the palladium catalyst is at least one of a polyvinyl alcohol polymer-palladium (PVA-Pd) catalyst, a polyvinyl pyrrolidone capped palladium (PVP-Pd) catalyst, a tin-palladium colloidal catalyst, and an ionic palladium catalyst.

7. The method according to claim 6, wherein the surface activation step includes activating the modification layer with a second aqueous solution containing the palladium catalyst to form the activation layer; wherein, in the second aqueous solution, a concentration of the palladium catalyst ranges from 20 ppm to 120 ppm.

8. The method according to claim 1, wherein the copper layer formation step includes sequentially forming a first copper layer and a second copper layer on the surface of the activation layer away from the polymer substrate, and the first copper layer and the second copper layer together constitute the ultra-thin copper foil; wherein the first copper layer is an electroless copper layer having a thickness ranging from 200 nanometers to 800 nanometers, and the second copper layer is an electroplated copper layer having a thickness ranging from 1 micrometer to 10 micrometers.

9. A carrier-attached ultra-thin copper foil comprising:
a polymer substrate;
a modification layer formed on at least one surface of the polymer substrate, wherein the modification layer is formed of an amine-based polymer compound;
an activation layer formed on a surface of the modification layer away from the polymer substrate, wherein the activation layer is formed of a palladium catalyst; and
an ultra-thin copper foil formed on a surface of the activation layer away from the modification layer;
wherein the polymer substrate is capable of being separated from the ultra-thin copper foil via the modification layer and the activation layer.

10. The carrier-attached ultra-thin copper foil according to claim 9, wherein the polymer substrate is a liquid crystal polymer substrate, and the amine-based polymer compound is polyethyleneimine (PEI); wherein a peeling strength of the polymer substrate separated from the ultra-thin copper foil through the modified layer and the activation layer is between 25 gf/cm and 40 gf/cm, measured according to JIS Z 0237-2009 standard.
